(19) United States
(12) Patent Application Publication
(10) Pub. No.: US 2026/0093650 A1
(43) Pub. Date: Apr. 2, 2026

(54) ELECTRONIC SYSTEM

(71) Applicant: PRIMAX ELECTRONICS LTD., Taipei City (TW)

(72) Inventors: CHAO-CHING WENG, Taipei City (TW); Jui-Min Wang, Taipei City (TW); Chung-Han Huang, Taipei City (TW)

(21) Appl. No.: 18/942,811

(22) Filed: Nov. 11, 2024

(30) Foreign Application Priority Data
Oct. 1, 2024 (TW) 113137655

(51) Int. Cl. G06F 13/38; G01R 33/07; G06F 13/40

(52) U.S. Cl. CPC G06F 13/382; G01R 33/072; G06F 13/4022; G06F 13/4081; G06F 2213/0042

(57) ABSTRACT

An electronic system includes a first electronic device and a second electronic device. The first electronic device includes a first processing unit, a first connection interface, a first switch and a first detection module. The first connection interface includes a first data transmission pin or a first control signal pin. The first switch is electrically connected with the first processing unit and the first data transmission pin or electrically connected with the first processing unit and the first control signal pin. The second electronic device includes a second processing unit, a second connection interface and a device identification component. The second connection interface is electrically connected with the second processing unit. If the first detection module detects the device identification component, the first processing unit is allowed to receive signals from the first data transmission pin or the first control signal pin through the first switch.

### FIELD OF THE INVENTION

The present invention relates to an electronic system, and more particularly to an electronic system with a default design.

### BACKGROUND OF THE INVENTION

Conventionally, when an electronic device (e.g., a first electronic device) is connected with another electronic device (e.g., a second electronic device) through connection interfaces (e.g., USB interfaces), the first electronic device is unable to know whether the second electronic device is a default electronic device in advance. Since the first electronic device is likely to receive unsafe or unexpected signals, these signals may cause damage or malfunction of the first electronic device. In other words, the existing electronic device needs a detection mechanism that is independent of the original connection interface to determine whether another electronic device to be connected to it can safely receive signals or communicate with each other according to the default design.

### SUMMARY OF THE INVENTION

The present invention provides an electronic system. The electronic system includes a first electronic device and a second electronic device. The first electronic device is provided with a detection module, and the second electronic device is provided with a corresponding device identification component. Consequently, the first electronic device is capable of judging whether the second electronic device is a default electronic device. According to the judging result, the first electronic device determines whether to receive signals from the second electronic device.

In accordance with an aspect of the present invention, an electronic system is provided. The electronic system includes a first electronic device and a second electronic device. The first electronic device includes a first processing unit, a first connection interface, a first switch and a first detection module. The first connection interface includes a first data transmission pin or a first control signal pin. The first switch is electrically connected with the first processing unit and the first data transmission pin or electrically connected with the first processing unit and the first control signal pin. The first detection module is electrically connected with the first switch. The second electronic device includes a second processing unit, a second connection interface and a device identification component. The second connection interface is electrically connected with the second processing unit. If the first detection module detects the device identification component after the first connection interface and the second connection interface are connected with each other, the first processing unit is allowed to receive signals from the first data transmission pin or the first control signal pin through the first switch, or the first processing unit is allowed to send signals to the first data transmission pin or the first control signal pin through the first switch.

In an embodiment, the first detection module is a magnetic sensor, and the device identification component is a magnetic element.

In an embodiment, the magnetic sensor is a Hall sensor, and the magnetic element is a magnet.

In an embodiment, the first connection interface is a USB Type C connection interface, the first control signal pin is a CC1pin, a CC2 pin, a SBU1 pin or a SUB2 pin, and the first data transmission pin is a TX1+ pin, a TX1- pin, a D+ pin, a D- pin, an RX1+ pin, an RX1- pin, a TX2+ pin, a TX2- pin, an RX2+ pin or an RX2- pin.

In accordance with another aspect of the present invention, an electronic system is provided. The electronic system includes a first electronic device and a second electronic device. The first electronic device includes a first processing unit, a first connection interface, a first switch, a first detection module and a first device identification component. The first connection interface includes a first data transmission pin or a first control signal pin. The first switch is electrically connected with the first processing unit and the first data transmission pin or electrically connected with the first processing unit and the first control signal pin. The first detection module is electrically connected with the first switch. The second electronic device includes a second processing unit, a second connection interface, a second switch, a second detection module and a second device identification component. The second connection interface includes a second data transmission pin or a second control signal pin. The second switch is electrically connected with the second processing unit and the second data transmission pin or electrically connected with the second processing unit and the second control signal pin. The second detection module is electrically connected with the second switch. If the first detection module detects the second device identification component after the first connection interface and the second connection interface are connected with each other, the first processing unit is allowed to receive signals from the first data transmission pin or the first control signal pin through the first switch, or the first processing unit is allowed to send signals to the first data transmission pin or the first control signal pin through the first switch. If the second detection module detects the first device identification component, the second processing unit is allowed to receive signals from the second data transmission pin or the second control signal pin through the second switch, or the second processing unit is allowed to send signals to the second data transmission pin or the second control signal pin through the second switch.

In an embodiment, the first detection module and the second detection module are magnetic sensors, and the first device identification component and the second device identification component are magnetic elements.

In an embodiment, the magnetic sensors are Hall sensors, and the magnetic elements are magnets.

In an embodiment, each of the first connection interface and the second connection interface is a USB Type C connection interface, each of the first control signal pin and the second control signal pin is a CC1 pin, a CC2 pin, a SBU1 pin or a SUB2 pin, and each of the first data transmission pin and the second data transmission pin is a TX1+ pin, a TX1- pin, a D+ pin, a D- pin, an RX1+ pin, an RX1- pin, a TX2+ pin, a TX2- pin, an RX2+ pin or an RX2- pin.

In accordance with another aspect of the present invention, an electronic system is provided. The electronic system includes a first electronic device and a second electronic device. The first electronic device includes a first processing unit, a first connection interface, a first switch and a first detection module. The first connection interface includes a first data transmission pin or a first control signal pin. The first switch is electrically connected with the first processing unit and the first data transmission pin or electrically connected with the first processing unit and the first control signal pin. The first detection module is electrically connected with the first switch. The first detection module includes a first light emitting terminal and a first light receiving terminal. The second electronic device includes a second processing unit, a second connection interface, a second switch and a second detection module. The second connection interface includes a second data transmission pin or a second control signal pin. The second switch is electrically connected with the second processing unit and the second data transmission pin or electrically connected with the second processing unit and the second control signal pin. The second detection module is electrically connected with the second switch. The second detection module includes a second light emitting terminal and a second light receiving terminal. If the first light receiving terminal receives a first light signal from the second light emitting terminal after the first connection interface and the second connection interface are connected with each other, the first processing unit is allowed to receive signals from the first data transmission pin or the first control signal pin through the first switch, or the first processing unit is allowed to send signals to the first data transmission pin or the first control signal pin through the first switch. If the second light receiving terminal receives a second light signal from the first light emitting terminal, the second processing unit is allowed to receive signals from the second data transmission pin or the second control signal pin through the second switch, or the second processing unit is allowed to send signals to the second data transmission pin or the second control signal pin through the second switch.

In an embodiment, each of the first connection interface and the second connection interface is a USB Type C connection interface, each of the first control signal pin and the second control signal pin is a CC1 pin, a CC2 pin, a SBU1 pin or a SUB2 pin, and each of the first data transmission pin and the second data transmission pin is a TX1+ pin, a TX1- pin, a D+ pin, a D- pin, an RX1+ pin, an RX1- pin, a TX2+ pin, a TX2- pin, an RX2+ pin or an RX2- pin.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic functional block diagram illustrating the architecture of an electronic system according to a first embodiment of the present invention;

FIG. 2 is a schematic functional block diagram illustrating the architecture of an electronic system according to a second embodiment of the present invention; and

FIG. 3 is a schematic functional block diagram illustrating the architecture of an electronic system according to a third embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

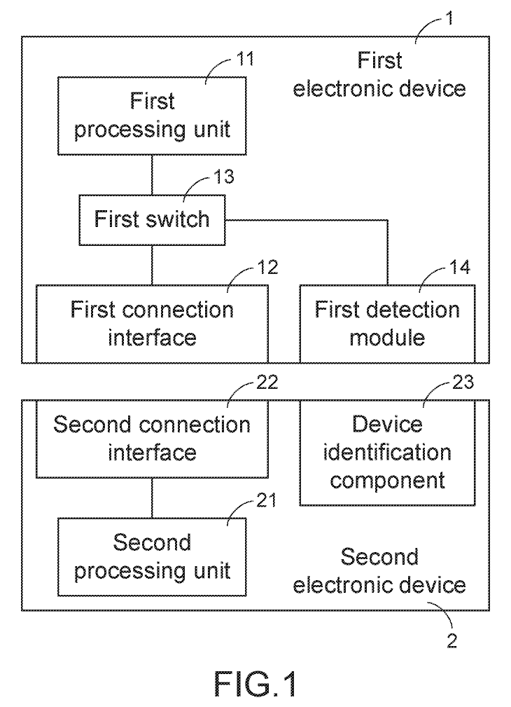

FIG. 1 is a schematic functional block diagram illustrating the architecture of an electronic system according to a first embodiment of the present invention. The electronic system includes a first electronic device 1 and a second electronic device 2.

The first electronic device 1 includes a first processing unit 11, a first connection interface 12, a first switch 13 and at least one first detection module 14.

The first processing unit 11 is a system on a chip (SoC), a central processing unit (CPU), a digital signal processor (DSP), a microprocessor (MPU), a microcontroller (MCU), a complex programmable logic device (CPLD), a field programmable gate array (FPGA), or a combination thereof.

The first connection interface 12 is a USB connection interface. For example, the first connection interface 12 is a USB Type C connection interface. In addition, the first connection interface 12 is a male connector or a female connector. The first connection interface 12 includes a first data transmission pin or a first control signal pin. In case that the first connection interface 12 is a USB Type C connection interface, the first control signal pin is a CC1 pin, a CC2 pin, a SBU1 pin or a SUB2 pin, and the first data transmission pin is a TX1+ pin, a TX1- pin, a D+ pin, a D- pin, an RX1+ pin, an RX1- pin, a TX2+ pin, a TX2- pin, an RX2+ pin or an RX2- pin.

In this embodiment, the first switch 13 is electrically connected with the first processing unit 11 and the first data transmission pin, or the first switch 13 is electrically connected with the first processing unit 11 and the first control signal pin. Through the first switch 13, the first processing unit 11 selectively receives signals from the first data transmission pin or the first control signal pin. When the first switch 13 is in an on state, signals can be transmitted between the first processing unit 11 and the first data transmission pin or between the first processing unit 11 and the first control signal pin. When the first switch 13 is in an off state, signals cannot be transmitted between the first processing unit 11 and the first data transmission pin or between the first processing unit 11 and the first control signal pin.

The first detection module 14 is electrically connected with the first switch 13. In addition, the first detection module 14 provides a detection result to the first switch 13. According to the detection result, the first switch 13 is switched from the on state to the off state, or the first switch 13 is switched from the off state to the on state, or the first switch 13 is maintained in the off state. In an embodiment, the first detection module 14 is a magnetic sensor, e.g., a Hall IC. According to the arrangement of the first switch 13 and the first detection module 14, the first electronic device 1 can prevent other non-default electronic devices from sending signals to the first processing unit 11 through the first data transmission pin or the first control signal pin of the connected first connection interface 12.

The second electronic device 2 includes a second processing unit 21, a second connection interface 22 and at least one device identification component 23.

The second processing unit 21 is a system on a chip (SoC), a central processing unit (CPU), a digital signal processor (DSP), a microprocessor (MPU), a microcontroller (MCU), a complex programmable logic device (CPLD), a field programmable gate array (FPGA), or a combination thereof.

The second connection interface 22 is electrically connected with the second processing unit 21. The signals generated by the second processing unit 21 can be transmitted to the first connection interface 12 of the first electronic device 1 (especially the first data transmission pin or the first control signal pin) through the second connection interface 22. Similarly, the second connection interface 22 is a USB connection interface, e.g., a USB Type C connection interface. In addition, the second connection interface 22 is a male connector or a female connector. The type of the second connection interface 22 is not restricted as long as it can be connected with the first connection interface 12. For example, in case that the first connection interface 12 is a USB Type C female connector, the second connection interface 22 is a USB Type C male connector.

The first connection interface 12 of the first electronic device 1 and the second connection interface 22 of the second electronic device 2 can be connected with each other in a direct manner or an indirect manner. If there is no other intermediate interface between the first connection interface 12 and the second connection interface 22, it means that the first connection interface 12 and the second connection interface 22 are connected with each other in the direct manner. If there is at least one intermediate interface between the first connection interface 12 and the second connection interface 22, it means that the first connection interface 12 and the second connection interface 22 are connected with each other in the indirect manner.

For example, if the first connection interface 12 is a USB Type C female connector and the second connection interface 22 is a USB Type C male connector, the first connection interface 12 and the second connection interface 22 are connected with each other in the direct manner after the second connection interface 22 is plugged into the first connection interface 12. Whereas, if both of the first connection interface 12 and the second connection interface 22 are USB Type C female connectors, a connecting cable is used as an intermediate interface to achieve the indirect connection between the first connection interface 12 and the second connection interface 22. Under this circumstance, the two terminals of the connecting cable are USB Type C male connectors. Consequently, the two terminals of the connecting cable are respectively plugged into the first connection interface 12 and the second connection interface 22.

The device identification component 23 is independent of the second connection interface 22. That is, the device identification component 23 and the second connection interface 22 are structurally independent of each other, and the device identification component 23 and the second connection interface 22 are not in communication with each other to exchange control signals. In an embodiment, the device identification component 23 is a magnetic element. For example, the device identification component 23 includes at least one magnet, or the device identification component 23 includes a magnetic conductor that is connected with the magnet.

In an embodiment, the structure or the number of the at least one first detection module 14 on the first electronic device 1 corresponds to the structure or the number of the at least one device identification component 23 on the second electronic device 2. Due to the preset agreement or setting, the first electronic device 1 can recognize whether the second electronic device 2 is a default electronic device.

For example, if the first detection module 14 can successfully detect all the device identification components 23 when the first electronic device 1 and the second electronic device 2 are close to each other and the first connection interface 12 and the second connection interface 22 are connected with each other, it means that the second electronic device 2 is the default electronic device. Meanwhile, the first detection module 14 issues a notification signal to the first switch 13. In response to the notification signal, the first switch 13 is switched from the off state to the on state. Under this circumstance, the first processing unit 11 is allowed to receive signals from the first data transmission pin or the first control signal pin through the first switch 13, or the first processing unit 11 is allowed to send signals to the first data transmission pin or the first control signal pin through the first switch 13.

Whereas, if the first detection module 14 does not detect all the device identification components 23, the first detection module 14 judges that the second electronic device 2 is a non-default electronic device. Meanwhile, the first detection module 14 issues a notification signal to the first switch 13. In response to the notification signal, the first switch 13 is maintained in the off state. Under this circumstance, the first processing unit 11 is not allowed to receive signals from the first data transmission pin or the first control signal pin through the first switch 13, or the first processing unit 11 is not allowed to send signals to the first data transmission pin or the first control signal pin through the first switch 13.

Due to the above protection mechanism, the protecting function can be achieved. For example, even if the non-default second electronic device 2 is electrically connected with the first connection interface 12 of the first electronic device 1 through the second connection interface 22, the first electronic device 1 will not receive signals from the non-default second electronic device 2.

In the electronic system of the first embodiment, the first electronic device 1 is equipped with the first switch 13 and the at least one first detection module 14. Correspondingly, the second electronic device 2 is equipped with the at least one device identification components 23. Due to the cooperation of the first detection module 14 and the device identification component 23, the first electronic device 1 can recognize that the second electronic device 2 is the default electronic device.

In a second embodiment of the electronic system, the first electronic device is further equipped with a device identification component, and the second electronic device is further equipped with a second switch and a second detection module. Consequently, the safety in the signal communication process will be enhanced.

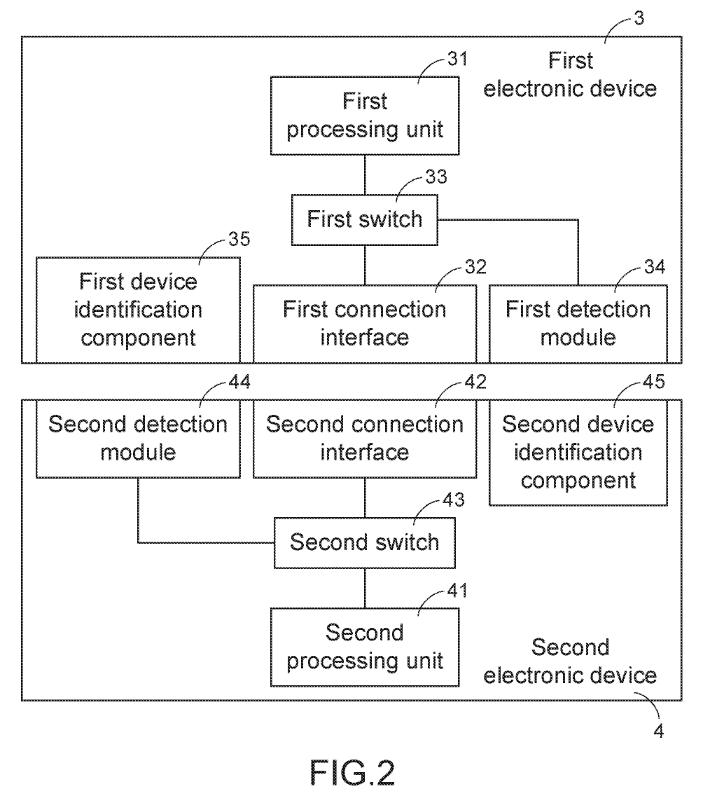

FIG. 2 is a schematic functional block diagram illustrating the architecture of an electronic system according to a second embodiment of the present invention. The electronic system includes a first electronic device 3 and a second electronic device 4.

The first electronic device 3 includes a first processing unit 31, a first connection interface 32, a first switch 33, a first detection module 34 and at least one first device identification component 35.

The first processing unit 31 is a system on a chip (SoC), a central processing unit (CPU), a digital signal processor (DSP), a microprocessor (MPU), a microcontroller (MCU), a complex programmable logic device (CPLD), a field programmable gate array (FPGA), or a combination thereof.

The first connection interface 32 is a USB connection interface. For example, the first connection interface 32 is a USB Type C connection interface. In addition, the first connection interface 32 is a male connector or a female connector. The first connection interface 32 includes a first data transmission pin or a first control signal pin. In case that the first connection interface 32 is a USB Type C connection interface, the first control signal pin is a CC1 pin, a CC2 pin, a SBU1 pin or a SUB2 pin, and the first data transmission pin is a TX1+ pin, a TX1- pin, a D+ pin, a D- pin, an RX1+ pin, an RX1- pin, a TX2+ pin, a TX2- pin, an RX2+ pin or an RX2- pin.

In this embodiment, the first switch 33 is electrically connected with the first processing unit 31 and the first data transmission pin of the first connection interface 32, or the first switch 33 is electrically connected with the first processing unit 31 and the first control signal pin of the first connection interface 32. Through the first switch 33, the first processing unit 31 selectively receives signals from the first data transmission pin or the first control signal pin. When the first switch 33 is in an on state, signals can be transmitted between the first processing unit 31 and the first data transmission pin or between the first processing unit 31 and the first control signal pin. When the first switch 33 is in an off state, signals cannot be transmitted between the first processing unit 31 and the first data transmission pin or between the first processing unit 31 and the first control signal pin.

The first detection module 34 is electrically connected with the first switch 33. In addition, the first detection module 34 provides a detection result to the first switch 33. According to the detection result, the first switch 33 is switched from the on state to the off state, or the first switch 33 is switched from the off state to the on state, or the first switch 33 is maintained in the off state. In an embodiment, the first detection module 34 is a magnetic sensor, e.g., a Hall IC. According to the settings of the first switch 33 and the first detection module 34, the first electronic device 3 can prevent other non-default electronic devices from sending signals to the first processing unit 31 through the first data transmission pin or the first control signal pin of the connected first connection interface 32.

The first device identification component 35 is independent of the first connection interface 32. That is, the first device identification component 35 and the first connection interface 32 are structurally independent of each other, and the first device identification component 35 and the first connection interface 32 are not in communication with each other to exchange control signals. In an embodiment, the first device identification component 35 is a magnetic element. For example, the first device identification component 35 includes at least one magnet, or the first device identification component 35 includes a magnetic conductor that is connected with the magnet.

The second electronic device 4 includes a second processing unit 41, a second connection interface 42, a second switch 43, a second detection module 44 and at least one second device identification component 45.

The second processing unit 41 is a system on a chip (SoC), a central processing unit (CPU), a digital signal processor (DSP), a microprocessor (MPU), a microcontroller (MCU), a complex programmable logic device (CPLD), a field programmable gate array (FPGA), or a combination thereof.

Similarly, the second connection interface 42 is a USB connection interface, e.g., a USB Type C connection interface. In addition, the second connection interface 42 is a male connector or a female connector. The second connection interface 42 includes a second data transmission pin or a second control signal pin. In case that the second connection interface 42 is a USB Type C connection interface, the second control signal pin is a CC1 pin, a CC2 pin, a SBU1 pin or a SUB2 pin, and the second data transmission pin is a TX1+ pin, a TX1- pin, a D+ pin, a D- pin, an RX1+ pin, an RX1- pin, a TX2+ pin, a TX2- pin, an RX2+ pin or an RX2- pin.

Similarly, the first connection interface 32 of the first electronic device 3 and the second connection interface 42 of the second electronic device 4 can be connected with each other in a direct manner or an indirect manner. The ways of connecting the first connection interface 32 with the second connection interface 42 in the direct manner or the indirect manner are similar to those of the first embodiment, and not redundantly described herein.

In this embodiment, the second switch 43 is electrically connected with the second processing unit 41 and the second data transmission pin of the second connection interface 42, or the second switch 43 is electrically connected with the second processing unit 41 and the second control signal pin of the second connection interface 42. Through the second switch 43, the second processing unit 41 selectively receives signals from the second data transmission pin or the second control signal pin. When the second switch 43 is in an on state, signals can be transmitted between the second processing unit 41 and the second data transmission pin or between the second processing unit 41 and the second control signal pin. When the second switch 43 is in an off state, signals cannot be transmitted between the second processing unit 41 and the second data transmission pin or between the second processing unit 41 and the second control signal pin.

The second detection module 44 is electrically connected with the second switch 43. In addition, the second detection module 44 provides a detection result to the second switch 43. According to the detection result, the second switch 43 is switched from the on state to the off state, or the second switch 43 is switched from the off state to the on state, or the second switch 43 is maintained in the off state. In an embodiment, the second detection module 44 is a magnetic sensor, e.g., a Hall IC. According to the arrangement of the second switch 43 and the second detection module 44, the second electronic device 4 can prevent other non-default electronic devices from sending signals to the second processing unit 41 through the second data transmission pin or the second control signal pin of the connected second connection interface 42.

The second device identification component 45 is independent of the second connection interface 42. That is, the second device identification component 45 and the second connection interface 42 are structurally independent of each other, and the second device identification component 45 and the second connection interface 42 are not in communication with each other to exchange control signals. In an embodiment, the second device identification component 45 is a magnetic element. For example, the second device identification component 45 includes at least one magnet, or the second device identification component 45 includes a magnetic conductor that is connected with the magnet.

In an embodiment, the structure or the number of the at least one first detection module 34 on the first electronic device 3 corresponds to the structure or the number of the at least one second device identification component 45 on the second electronic device 4. Similarly, the structure or the number of the at least one second detection module 44 on the second electronic device 4 corresponds to the structure or the number of the at least one first device identification component 35 on the first electronic device 3. Due to the preset agreement or setting, the first electronic device 3 and the second electronic device 4 are default electronic devices for each other.

For example, if the first detection module 34 can successfully detect all the second device identification components 45 when the first electronic device 3 and the second electronic device 4 are close to each other and the first connection interface 32 and the second connection interface 42 are connected with each other, it means that the second electronic device 4 is the default electronic device. Meanwhile, the first detection module 34 issues a notification signal to the first switch 33. In response to the notification signal, the first switch 33 is switched from the off state to the on state. Under this circumstance, the first processing unit 31 is allowed to receive signals from the first data transmission pin or the first control signal pin through the first switch 33, or the first processing unit 31 is allowed to send signals to the first data transmission pin or the first control signal pin through the first switch 33.

Similarly, if the second detection module 44 can successfully detect all the first device identification components 35, it means that the first electronic device 3 is the default electronic device. Meanwhile, the second detection module 44 issues a notification signal to the second switch 43. In response to the notification signal, the second switch 43 is switched from the off state to the on state. Under this circumstance, the second processing unit 41 is allowed to receive signals from the second data transmission pin or the second control signal pin through the second switch 43, or the second processing unit 41 is allowed to send signals to the second data transmission pin or the second control signal pin through the second switch 43.

When the first switch 33 and the second switch 43 are both in the on state, the first electronic device 3 and the second electronic device 4 can be in communication with each other to transmit signals through the first connection interface 32 and the second connection interface 42.

Whereas, if the first detection module 34 can not detect all the second device identification components 45, the first detection module 34 judges that the second electronic device 4 is a non-default electronic device. Meanwhile, the first detection module 34 issues a notification signal to the first switch 33. In response to the notification signal, the first switch 33 is maintained in the off state. Under this circumstance, the first processing unit 31 is not allowed to receive signals from the first data transmission pin or the first control signal pin through the first switch 33, or the first processing unit 31 is not allowed to send signals to the first data transmission pin or the first control signal pin through the first switch 33. Since the first electronic device 3 is protected from receiving signals from the second electronic device 4, the protecting efficacy is achieved.

Similarly, if the second detection module 44 can not detect all the first device identification components 35, the second detection module 44 judges that the first electronic device 3 is a non-default electronic device. Meanwhile, the second detection module 44 issues a notification signal to the second switch 43. In response to the notification signal, the second switch 43 is maintained in the off state. Under this circumstance, the second processing unit 41 is not allowed to receive signals from the second data transmission pin or the second control signal pin through the second switch 43, or the second processing unit 41 is not allowed to send signals to the second data transmission pin or the second control signal pin through the second switch 43. Since the second electronic device 4 is protected from receiving signals from the first electronic device 3, the protecting efficacy is achieved.

Due to the double detection mechanism of this embodiment, the security of transmitting signals between the first electronic device 3 and the second electronic device 4 will be further enhanced.

In the electronic system of the second embodiment, the first electronic device 3 and the second electronic device 4 confirm whether the other party is a default electronic device according to a magnetic detection technology.

The present invention further provides an electronic system according to a third embodiment. In the third embodiment, the first electronic device and the second electronic device confirm whether the other party is a default electronic device according to an optical detection technology.

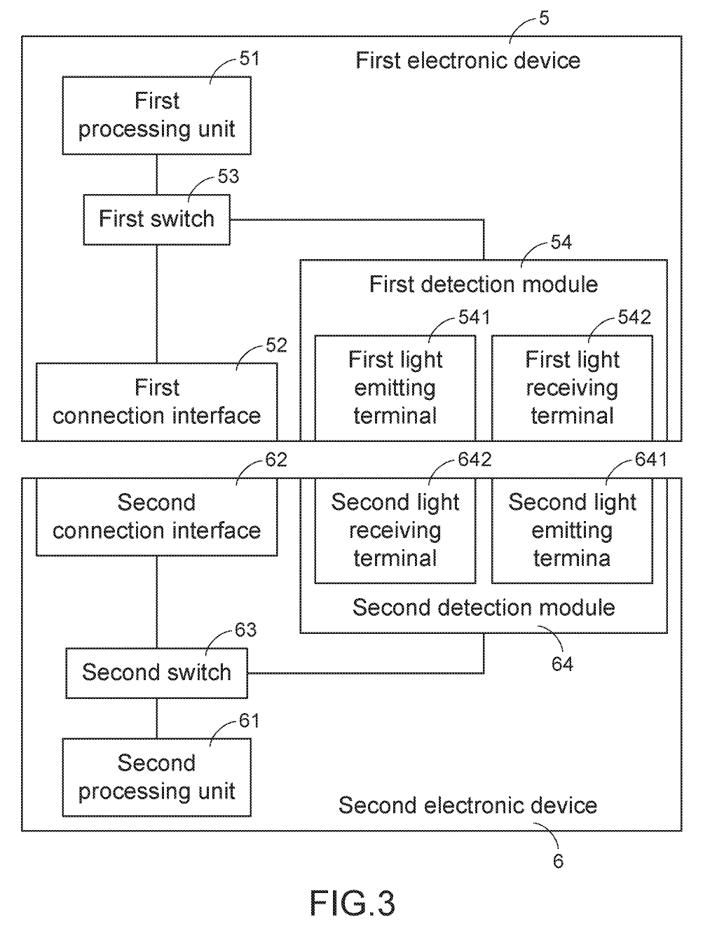

FIG. 3 is a schematic functional block diagram illustrating the architecture of an electronic system according to a third embodiment of the present invention. The electronic system includes a first electronic device 5 and a second electronic device 6.

The first electronic device 5 includes a first processing unit 51, a first connection interface 52, a first switch 53 and a first detection module 54.

The first processing unit 51 is a system on a chip (SoC), a central processing unit (CPU), a digital signal processor (DSP), a microprocessor (MPU), a microcontroller (MCU), a complex programmable logic device (CPLD), a field programmable gate array (FPGA), or a combination thereof.

The first connection interface 52 is a USB connection interface. For example, the first connection interface 52 is a USB Type C connection interface. In addition, the first connection interface 52 is a male connector or a female connector. The first connection interface 52 includes a first data transmission pin or a first control signal pin. In case that the first connection interface 52 is a USB Type C connection interface, the first control signal pin is a CC1 pin, a CC2 pin, a SBU1 pin or a SUB2 pin, and the first data transmission pin is a TX1+ pin, a TX1- pin, a D+ pin, a D- pin, an RX1+ pin, an RX1- pin, a TX2+ pin, a TX2- pin, an RX2+ pin or an RX2- pin.

In this embodiment, the first switch 53 is electrically connected with the first processing unit 51 and the first data transmission pin of the first connection interface 52, or the first switch 53 is electrically connected with the first processing unit 51 and the first control signal pin of the first connection interface 52. Through the first switch 53, signals can be selectively transmitted between the first connection interface 52 and the first processing unit 51. When the first switch 53 is in an on state, signals can be transmitted between the first processing unit 51 and the first data transmission pin or between the first processing unit 51 and the first control signal pin. When the first switch 53 is in an off state, signals cannot be transmitted between the first processing unit 51 and the first data transmission pin or between the first processing unit 51 and the first control signal pin.

The first detection module 54 is electrically connected with the first switch 53. In addition, the first detection module 54 provides a detection result to the first switch 53. According to the detection result, the first switch 53 is switched from the on state to the off state, or the first switch 53 is switched from the off state to the on state, or the first switch 53 is maintained in the off state. In an embodiment, the first detection module 54 includes at least one first light emitting terminal 541 and at least one first light receiving terminal 542.

The second electronic device 6 includes a second processing unit 61, a second connection interface 62, a second switch 63 and a second detection module 64.

The second processing unit 61 is a system on a chip (SoC), a central processing unit (CPU), a digital signal processor (DSP), a microprocessor (MPU), a microcontroller (MCU), a complex programmable logic device (CPLD), a field programmable gate array (FPGA), or a combination thereof.

Similarly, the second connection interface 62 is a USB connection interface, e.g., a USB Type C connection interface. In addition, the second connection interface 62 is a male connector or a female connector. The second connection interface 62 includes a second data transmission pin or a second control signal pin. In case that the second connection interface 62 is a USB Type C connection interface, the second control signal pin is a CC1 pin, a CC2 pin, a SBU1 pin or a SUB2 pin, and the second data transmission pin is a TX1+ pin, a TX1- pin, a D+ pin, a D- pin, an RX1+ pin, an RX1- pin, a TX2+ pin, a TX2- pin, an RX2+ pin or an RX2- pin.

In this embodiment, the second switch 63 is electrically connected with the second processing unit 61 and the second data transmission pin of the second connection interface 62, or the second switch 63 is electrically connected with the second processing unit 61 and the second control signal pin of the second connection interface 62. Through the second switch 63, signals can be selectively transmitted between the second processing unit 61 and the second processing unit 61. When the second switch 63 is in an on state, signals can be transmitted between the second processing unit 61 and the second data transmission pin or between the second processing unit 61 and the second control signal pin. When the second switch 63 is in an off state, signals cannot be transmitted between the second processing unit 61 and the second data transmission pin or between the second processing unit 61 and the second control signal pin.

The second detection module 64 is electrically connected with the second switch 63. In addition, the second detection module 64 provides a detection result to the second switch 63. According to the detection result, the second switch 63 is switched from the on state to the off state, or the second switch 63 is switched from the off state to the on state, or the second switch 63 is maintained in the off state. In an embodiment, the second detection module 64 includes at least one second light emitting terminal 641 and at least one second light receiving terminal 642.

In an embodiment, the structure or the number of the at least one first light emitting terminal 541 in the first detection module 54 corresponds to the structure or the number of the at least one second light receiving terminal 642 in the second detection module 64. Similarly, the structure or the number of the at least one first light receiving terminal 542 in the first detection module 54 corresponds to the structure or the number of the at least one second light emitting terminal 641 in the second detection module 64. Due to the preset agreement or setting, the first electronic device 5 and the second electronic device 6 are default electronic devices for each other.

For example, if the light signal from the first light emitting terminal 541 is successfully received or detected by the second light receiving terminal 642 when the first electronic device 5 and the second electronic device 6 are close to each other and the first connection interface 52 and the second connection interface 62 are connected with each other, it means that the first electronic device 5 is the default electronic device. Meanwhile, the second detection module 64 issues a notification signal to the second switch 63. In response to the notification signal, the second switch 63 is switched from the off state to the on state. Under this circumstance, the second processing unit 61 is allowed to receive signals from the second data transmission pin or the second control signal pin through the second switch 63, or the second processing unit 61 is allowed to send signals to the second data transmission pin or the second control signal pin through the second switch 63.

Similarly, if the light signal from the second light emitting terminal 641 is successfully received or detected by the first light receiving terminal 542, it means that the second electronic device 6 is the default electronic device. Meanwhile, the second detection module 64 issues a notification signal to the second switch 63. In response to the notification signal, the second switch 63 is switched from the off state to the on state. Meanwhile, the first detection module 54 issues a notification signal to the first switch 53. In response to the notification signal, the first switch 53 is switched from the off state to the on state. Under this circumstance, the first processing unit 51 is allowed to receive signals from the first data transmission pin or the first control signal pin through the first switch 53, or the first processing unit 51 is allowed to send signals to the first data transmission pin or the first control signal pin through the first switch 53.

When the first switch 53 and the second switch 63 are both in the on state, the first electronic device 5 and the second electronic device 6 can be in communication with each other to transmit signals through the first connection interface 52 and the second connection interface 62.

Whereas, if the light signal from the first light emitting terminal 541 is not successfully received or detected by the second light receiving terminal 642, the second detection module 64 judges that the first electronic device 5 is a non-default electronic device. Meanwhile, the second detection module 64 issues a notification signal to the second switch 63. In response to the notification signal, the second switch 63 is maintained in the off state. Under this circumstance, the second processing unit 61 is not allowed to receive signals from the second data transmission pin or the second control signal pin through the second switch 63, or the second processing unit 61 is not allowed to send signals to the second data transmission pin or the second control signal pin through the second switch 63.

Similarly, if the light signal from the second light emitting terminal 641 is not successfully received or detected by the first light receiving terminal 542, the first detection module 54 judges that the second electronic device 6 is the non-default electronic device. Meanwhile, the first detection module 54 issues a notification signal to the first switch 53. In response to the notification signal, the first switch 53 is maintained in the off state. Under this circumstance, the first processing unit 51 is not allowed to receive signals from the first data transmission pin or the first control signal pin through the first switch 53, or the first processing unit 51 is not allowed to send signals to the first data transmission pin or the first control signal pin through the first switch 53. In other words, the signal communication and transmission between the first electronic device 5 and the second electronic device 6 cannot be achieved.

Due to the double detection mechanism of this embodiment, the security of transmitting signals between the first electronic device 5 and the second electronic device 6 will be further enhanced.

In the above embodiments, each of the first electronic device and the second electronic device is a camera, a speaker, a microphone, a tablet computer or a docking station for expanding the functionality of the electronic device. For example, in case that the first electronic device is a camera and the second electronic device is a default speaker, the second electronic device can be connected to the first electronic device to expand or increase the sound output function that the original camera does not have.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

WHAT IS CLAIMED IS:

1. An electronic system, comprising:
a first electronic device comprising a first processing unit, a first connection interface, a first switch and a first detection module, wherein the first connection interface comprises a first data transmission pin or a first control signal pin, the first switch is electrically connected with the first processing unit and the first data transmission pin or electrically connected with the first processing unit and the first control signal pin, and the first detection module is electrically connected with the first switch; and
a second electronic device comprising a second processing unit, a second connection interface and a device identification component, wherein the second connection interface is electrically connected with the second processing unit,
wherein if the first detection module detects the device identification component after the first connection interface and the second connection interface are connected with each other, the first processing unit is allowed to receive signals from the first data transmission pin or the first control signal pin through the first switch, or the first processing unit is allowed to send signals to the first data transmission pin or the first control signal pin through the first switch.

2. The electronic system according to claim 1, wherein the first detection module is a magnetic sensor, and the device identification component is a magnetic element.

3. The electronic system according to claim 2, wherein the magnetic sensor is a Hall sensor, and the magnetic element is a magnet.

4. The electronic system according to claim 1, wherein the first connection interface is a USB Type C connection interface, the first control signal pin is a CC1 pin, a CC2 pin, a SBU1 pin or a SUB2 pin, and the first data transmission pin is a TX1+ pin, a TX1- pin, a D+ pin, a D- pin, an RX1+ pin, an RX1- pin, a TX2+ pin, a TX2- pin, an RX2+ pin or an RX2- pin.

5. An electronic system, comprising:
a first electronic device comprising a first processing unit, a first connection interface, a first switch, a first detection module and a first device identification component, wherein the first connection interface comprises a first data transmission pin or a first control signal pin, the first switch is electrically connected with the first processing unit and the first data transmission pin or electrically connected with the first processing unit and the first control signal pin, and the first detection module is electrically connected with the first switch; and
a second electronic device comprising a second processing unit, a second connection interface, a second switch, a second detection module and a second device identification component, wherein the second connection interface comprises a second data transmission pin or a second control signal pin, the second switch is electrically connected with the second processing unit and the second data transmission pin or electrically connected with the second processing unit and the second control signal pin, and the second detection module is electrically connected with the second switch,
wherein if the first detection module detects the second device identification component after the first connection interface and the second connection interface are connected with each other, the first processing unit is allowed to receive signals from the first data transmission pin or the first control signal pin through the first switch, or the first processing unit is allowed to send signals to the first data transmission pin or the first control signal pin through the first switch,
wherein if the second detection module detects the first device identification component, the second processing unit is allowed to receive signals from the second data transmission pin or the second control signal pin through the second switch, or the second processing unit is allowed to send signals to the second data transmission pin or the second control signal pin through the second switch.

6. The electronic system according to claim 5, wherein the first detection module and the second detection module are magnetic sensors, and the first device identification component and the second device identification component are magnetic elements.

7. The electronic system according to claim 6, wherein the magnetic sensors are Hall sensors, and the magnetic elements are magnets.

8. The electronic system according to claim 5, wherein each of the first connection interface and the second connection interface is a USB Type C connection interface, each of the first control signal pin and the second control signal pin is a CC1 pin, a CC2 pin, a SBU1 pin or a SUB2 pin, and each of the first data transmission pin and the second data transmission pin is a TX1+ pin, a TX1- pin, a D+ pin, a D- pin, an RX1+ pin, an RX1- pin, a TX2+ pin, a TX2- pin, an RX2+ pin or an RX2- pin.

9. An electronic system, comprising:
a first electronic device comprising a first processing unit, a first connection interface, a first switch and a first detection module, wherein the first connection interface comprises a first data transmission pin or a first control signal pin, the first switch is electrically connected with the first processing unit and the first data transmission pin or electrically connected with the first processing unit and the first control signal pin, and the first detection module is electrically connected with the first switch, wherein the first detection module comprises a first light emitting terminal and a first light receiving terminal; and
a second electronic device comprising a second processing unit, a second connection interface, a second switch and a second detection module, wherein the second connection interface comprises a second data transmission pin or a second control signal pin, the second switch is electrically connected with the second processing unit and the second data transmission pin or electrically connected with the second processing unit and the second control signal pin, and the second detection module is electrically connected with the second switch, wherein the second detection module comprises a second light emitting terminal and a second light receiving terminal,
wherein if the first light receiving terminal receives a first light signal from the second light emitting terminal after the first connection interface and the second connection interface are connected with each other, the first processing unit is allowed to receive signals from the first data transmission pin or the first control signal pin through the first switch, or the first processing unit is allowed to send signals to the first data transmission pin or the first control signal pin through the first switch,
wherein if the second light receiving terminal receives a second light signal from the first light emitting terminal, the second processing unit is allowed to receive signals from the second data transmission pin or the second control signal pin through the second switch, or the second processing unit is allowed to send signals to the second data transmission pin or the second control signal pin through the second switch.

10. The electronic system according to claim 9, wherein each of the first connection interface and the second connection interface is a USB Type C connection interface, each of the first control signal pin and the second control signal pin is a CC1 pin, a CC2 pin, a SBU1 pin or a SUB2 pin, and each of the first data transmission pin and the second data transmission pin is a TX1+ pin, a TX1- pin, a D+ pin, a D- pin, an RX1+ pin, an RX1- pin, a TX2+ pin, a TX2- pin, an RX2+ pin or an RX2- pin.
